(19) United States
(12) Patent Application Publication
(10) Pub. No.: US 2013/0100630 A1
(43) Pub. Date: Apr. 25, 2013

(54) ELECTRONIC DEVICE WITH CABLE CLAMPING APPARATUS

(71) Applicant: AN-GANG LIANG, Shenzhen City (CN)

(72) Inventor: AN-GANG LIANG, Shenzhen City (CN)

(73) Assignees: HON HAI PRECISION INDUSTRY CO., LTD., Tu-Cheng (TW); HONG FU JIN PRECISION INDUSTRY (ShenZhen) Co., LTD., Shenzhen City (CN)

(21) Appl. No.: 13/308,564

(22) Filed: Dec. 1, 2011

(30) Foreign Application Priority Data
Oct. 19, 2011 (CN) 201110318167.9

(51) Int. Cl. H05K 7/14; H02G 3/32

(52) U.S. Cl. 361/807; 174/70 R

(57) ABSTRACT

A cable clamping apparatus includes a bracket and a number of cable clamps connected to the bracket. Each cable clamp includes a fixing plate fixed to the bracket, and a clamping portion extending from the fixing plate for clamping a power cable together with the bracket.

### BACKGROUND

1. Technical Field

The present disclosure relates to an electronic device with a cable clamping apparatus.

2. Description of Related Art

An electronic device, such as a server, generally includes a chassis and a power cable with a connector. When the connector is not connected to a power source, the power cable is usually just left hanging there in a disorderly manner, and may even becoming entangled with other equipment if the device is moved to another location, which can cause damage.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device; the electronic device includes a plurality of cable clamps.

FIG. 2 is an enlarged view of one of the cable clamps of FIG. 1.

FIG. 3 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

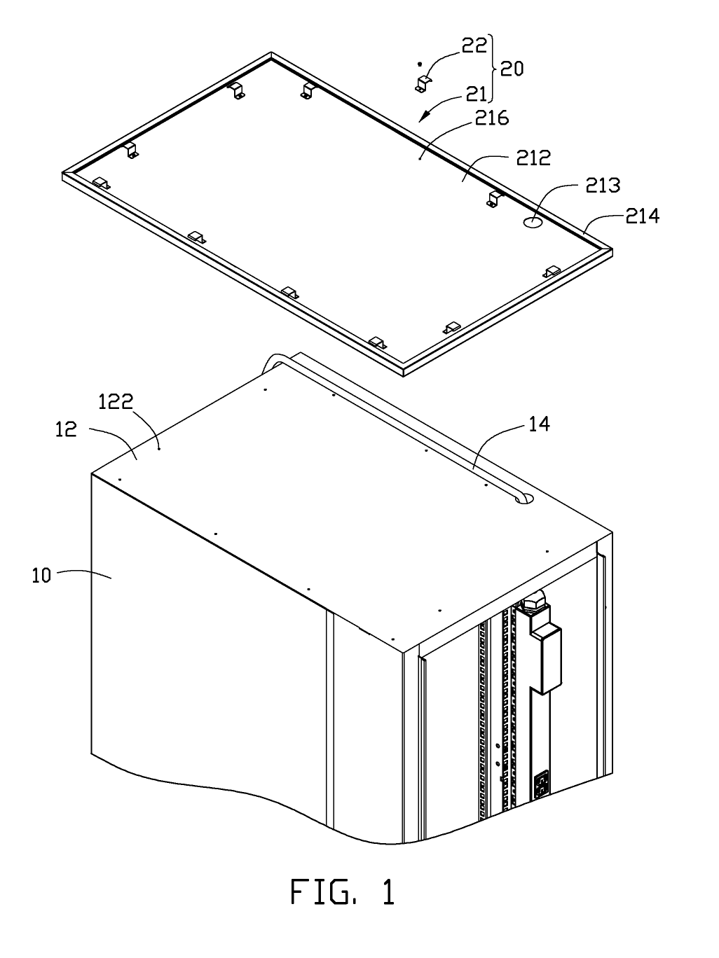

Referring to FIG. 1, an embodiment of an electronic device includes a rack 10 and a cable clamping apparatus 20.

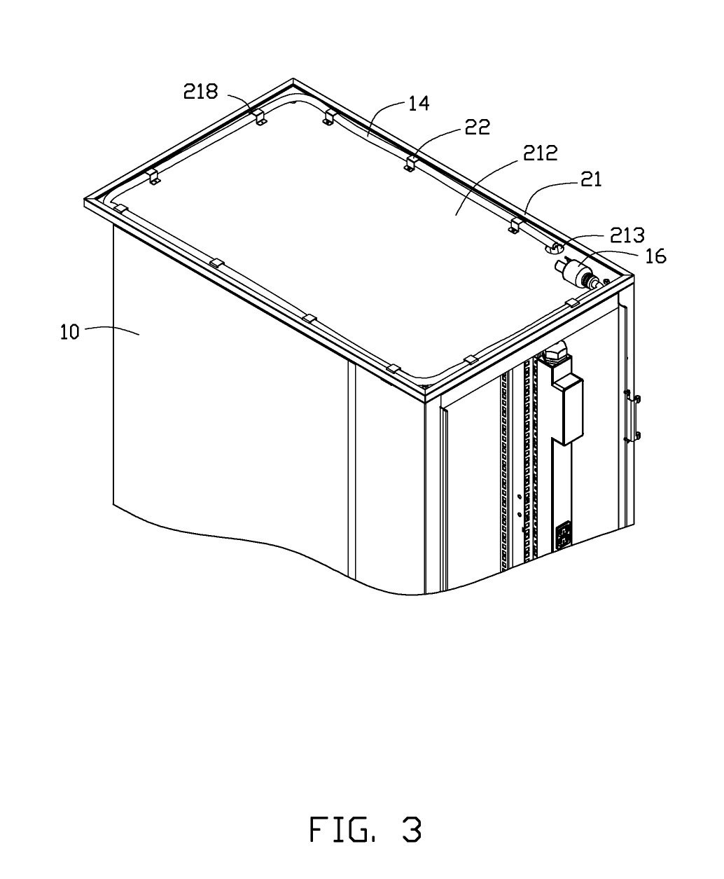

The rack 10 includes a top wall 12, a power cable 14 extending out of the rack 10 through the top wall 12, and a connector 16 (shown in FIG. 3) connected to a distal end of the power cable 14 located outside the rack 10. The top wall 12 defines a plurality of screw holes 122 respectively adjacent to four edges of the top wall 12.

The cable clamping apparatus 20 includes a bracket 21 and a plurality of cable clamps 22. The bracket 21 includes a supporting plate 212 and four flanges 214 respectively extending up from four sides of the supporting plate 212. The supporting plate 212 defines a through hole 213 adjacent to one of the flanges 214, and defines a plurality of fastening holes 216 respectively adjacent to the flanges 214.

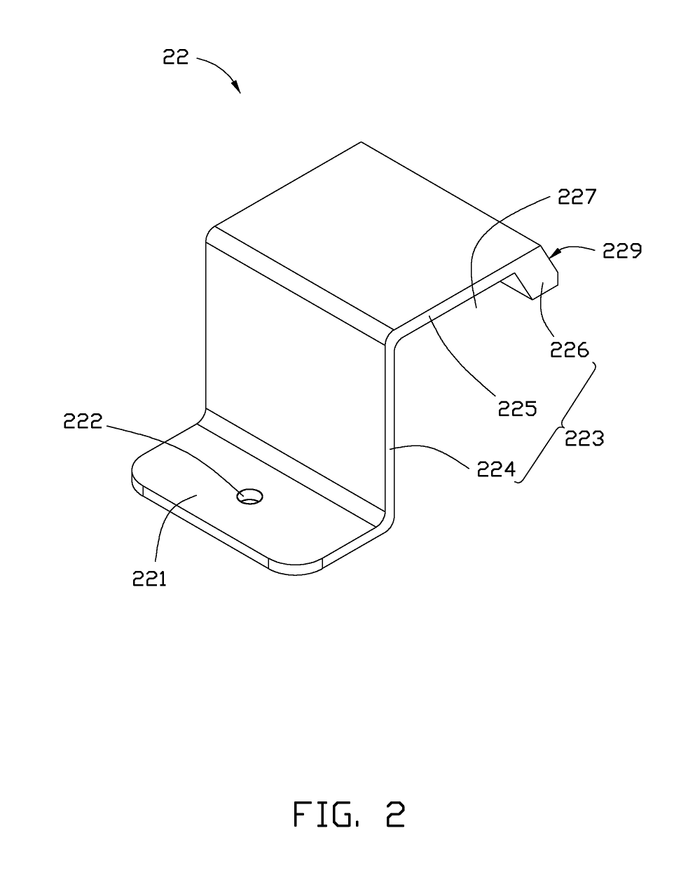

Referring to FIG. 2, each cable clamp 22 includes a fixing plate 221 and a resilient clamping portion 223 extending up from a side of the fixing plate 221. The clamping portion 223 includes an extending plate 224 extending up from the fixing plate 221, a connecting plate 225 extending from a distal end of the extending plate 224 away from the fixing plate 221, and a latching plate 226 slantingly extending down from a distal end of the connecting plate 225 opposite to the extending plate 224. The connecting plate 225 is substantially parallel to the fixing plate 221. The extending plate 224, the connecting plate 225, and the latching plate 226 cooperatively bound a receiving space 227. An outer surface of the latching plate 226 forms a guiding surface 229. The fixing plate 221 defines a fixing hole 222.

Referring to FIG. 3, in assembly, the connector 16 extends through the through hole 213 from a bottom of the supporting plate 212. The bracket 10 is supported on the top wall 12. The fastening holes 216 are aligned with the corresponding screw holes 122. The fixing plate 221 of each cable clamp 22 is supported on the supporting plate 212. The fixing hole 222 is aligned with a corresponding fastening hole 216. A screw 30 is extended through the fixing hole 222 and the fastening hole 216, to be screwed into the corresponding screw hole 122. The guiding surface 229 of each cable clamp 22 faces the corresponding flange 214, and the latching plate 226 and the corresponding flange 214 cooperatively bound an access 218 for the receiving space 227 above the supporting plate 212, which is less than a diameter of the power cable 14.

In use, the power cable 14 is pressed on the corresponding guiding surfaces 229 to deform the clamping portions 223, thereby enlarging the accesses 218, until entering the receiving spaces 227 through the corresponding accesses 218. The clamping portions 223 are restored to hold the power cable 14 with the flanges 214.

When disassembling the power cable 14 from the cable clamps 22, the clamping portions 223 are deformed away from the corresponding flanges 214 to enlarge the accesses 218. At which time the power cable 14 may be easily separated from the cable clamps 22.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A cable clamping apparatus comprising:
a bracket; and
a plurality of cable clamps connected to the bracket, wherein each cable clamp comprises a fixing plate mounted on the bracket and a clamping portion extending from the fixing plate for clamping a power cable together with the bracket.

2. The cable clamping apparatus of claim 1, wherein the clamping portion is resilient, and comprises an extending plate extending up from the fixing plate, a connecting plate extending from the extending plate away from the fixing plate, and a latching plate extending down from a distal end of the connecting plate, wherein the extending plate, the connecting plate, and the latching plate cooperatively bound a receiving space to receive the power cable.

3. The cable clamping apparatus of claim 2, wherein the bracket comprises a supporting plate and a flange extending up from the supporting plate, the fixing plate of each cable clamp is fixed to the supporting plate adjacent to the flange, an access communicating with the receiving space is defined between the latching plate and the flange, the power cable is operable to enter the receiving space through the access.

4. The cable clamping apparatus of claim 3, wherein the fixing plate defines a fixing hole, a screw extends through the fixing hole to be fixed to the supporting plate.

5. The cable clamping apparatus of claim 3, wherein a slanted guiding surface is formed on an outer surface of the latching plate.

6. The cable clamping apparatus of claim 3, wherein the supporting plate defines a through hole through which the power cable extends.

7. An electronic device, comprising:
a rack;
a power cable extending out of the rack; and
a cable clamping apparatus comprising a bracket mounted to the rack and a plurality of cable clamps, each cable clamp comprising a fixing plate mounted to the bracket and a clamping portion extending from the fixing plate for clamping the power cable together with the bracket.

8. The electronic device of claim 7, wherein the clamping portion is resilient, and comprises an extending plate extending up from the fixing plate, a connecting plate extending from the extending plate away from the fixing plate, and a latching plate extending down from a distal end of the connecting plate, wherein the extending plate, the connecting plate, and the latching plate cooperatively bound a receiving space to receive the power cable.

9. The electronic device of claim 8, wherein the bracket comprises a supporting plate and a flange extending up from the supporting plate, the fixing plate of each cable clamp is fixed to the supporting plate adjacent to the flange, an access communicating with the receiving space is defined between the latching plate and the flange, the power cable is operable to enter the receiving space through the access.

10. The electronic device of claim 9, wherein the supporting plate defines a plurality of fastening holes adjacent to the flange, the fixing plate of each cable clamp defines a fixing hole, the rack comprises a top wall defining a plurality of screw holes corresponding with the fastening holes, a plurality of screws extend through the fixing holes and the fastening holes, to be screwed into the corresponding screw holes.
